(19) United States
(12) Patent Application Publication
(10) Pub. No.: US 2023/0354598 A1
(43) Pub. Date: Nov. 2, 2023

(54) Memory and Method for Forming the Same

(71) Applicant: Shanghai Huahong Grace Semiconductor Manufacturing Corporation, Shanghai (CN)

(72) Inventor: Binghan LI, Shanghai (CN)

(73) Assignee: Shanghai Huahong Grace Semiconductor Manufacturing Corporation, Shanghai (CN)

(21) Appl. No.: 18/190,569

(22) Filed: Mar. 27, 2023

(30) Foreign Application Priority Data
Apr. 29, 2022 (CN) 202210468715.4

(51) Int. Cl. H10B 41/30; H01L 29/423

(52) U.S. Cl. CPC H10B 41/30; H01L 29/42328

(57) ABSTRACT

The present disclosure provides a memory and a method for forming the same. The memory includes: a substrate including a first region, a second region and a third region; a floating gate structure disposed on the second region of the substrate; a first side wall disposed on the floating gate structure; a first gate structure disposed on a side of the floating gate structure, wherein the first gate structure is electrically coupled with the floating gate structure; a dielectric structure disposed on a surface of the first gate structure; a source line structure disposed on a surface of the dielectric structure, wherein the source line structure is also disposed on a surface of the first region; and a word line gate structure disposed on the third region. Therefore, the performance of the memory can be improved.

### CROSS-REFERENCE TO RELATED APPLICATIONS

This application claims the benefit of priority to Chinese patent application No. 202210468715.4, filed on Apr. 29, 2022, the entire disclosures of which are incorporated herein by reference.

### TECHNICAL FIELD

The present disclosure relates to the technical field of semiconductors, and more particularly to a memory and a method for forming the memory.

### BACKGROUND

In current semiconductor industry, integrated circuit products can be divided into three major types: analog circuit, digital circuit and digital/analog hybrid circuit. Memory is an important type of digital circuit. In memory, flash memory has developed rapidly in recent years. The flash memory can store information for a long time without power, and has high integration, fast storage speed, easy erasure and rewriting. Therefore, the flash memory has been widely used in many fields such as microcomputer and automatic control.

There are two types of flash memory: stack gate flash memory and split gate flash memory. The stack gate flash memory has a floating gate and a control gate disposed above the floating gate. The stack gate flash memory may cause an over-erasure effect. Unlike the stack gate flash memory, the split gate flash memory forms a word line as an erasing gate on one side of a floating gate. Thus, the split gate flash memory can effectively avoid the over-erasure effect.

However, the performance of the existing split gate flash memory is poor.

### SUMMARY

The present disclosure provides a memory and a method for forming the memory, in order to improve the performance of the split gate flash memory.

According to an aspect of the present disclosure, a memory includes: a substrate including a first region, a second region and a third region, wherein the second region is disposed on two sides of the first region, and the second region is disposed between the first region and the third region; a floating gate structure disposed on the second region of the substrate; a first side wall disposed on the floating gate structure; a first gate structure disposed on a side of the floating gate structure, wherein the first gate structure is electrically coupled with the floating gate structure; a dielectric structure disposed on a surface of the first gate structure; a source line structure disposed on a surface of the dielectric structure, wherein the source line structure is also disposed on a surface of the first region; and a word line gate structure disposed on the third region.

According to some embodiments, the memory further includes an erasing gate structure disposed on the floating gate structure, wherein the erasing gate structure exposes a top surface of the floating gate structure, and the first side wall is disposed on the erasing gate structure.

According to some embodiments, the memory further includes an isolation structure disposed on a side surface of the erasing gate structure, wherein the first gate structure is disposed on a surface of the isolation structure and electrically coupled with the floating gate structure.

According to some embodiments, a part of the isolation structure is also disposed on the erasing gate structure.

According to some embodiments, the isolation structure has an L-shaped section along an arrangement direction of the first region, the second region and the third region.

According to some embodiments, the first gate structure includes a first gate layer disposed on the surface of the isolation structure and a second gate layer disposed on a surface of the first gate layer and on the isolation structure, and the second gate layer is disposed on the floating gate structure.

According to some embodiments, the source line structure includes a first source line layer disposed on the surface of the dielectric structure and a second source line layer disposed on a surface of the first source line layer and the surface of the first region.

According to some embodiments, the memory further includes a first doped region disposed in the first region, wherein the source line structure is electrically coupled with the first doped region.

According to some embodiments, the memory further includes a second doped region disposed in the first region and the second region, wherein the first doped region is disposed in the second doped region, and a conductive type of the first doped region is opposite to a conductive type of the second doped region.

According to some embodiments, the conductivity type of the second doped region is P-type, and the conductivity type of the first doped region is N-type.

According to some embodiments, the memory further includes a second side wall disposed on a side surface of the first side wall, a side surface of the erasing gate structure and a side surface of the floating gate structure.

According to some embodiments, the word line gate structure includes a word line gate dielectric layer disposed on a side surface of the second side wall and a surface of the third region, and a word line gate layer disposed on a surface of the word line gate dielectric layer.

According to some embodiments, the substrate further includes a fourth region and a third doped region, wherein the third region is disposed between the second region and the fourth region, and the third doped region is disposed in the third region and the fourth region.

According to some embodiments, the memory further includes: a first electrical coupling structure disposed on a top surface of the source line structure; a second electrical coupling structure disposed on a top surface of the word line gate structure; and a third electrical coupling structure disposed on a surface of the fourth region and electrically coupled with the third doped region.

According to some embodiments, the substrate includes a memory area and a peripheral area, and the memory area includes the first region, the second region, the third region and the fourth region, wherein the substrate further includes a control gate structure disposed on the peripheral area and a source-drain doped region disposed in the substrate on two sides of the control gate structure.

According to some embodiments, the memory further includes a third side wall disposed on a side of the word line gate structure.

According to some embodiments, the floating gate structure includes a floating gate dielectric layer and a floating gate layer disposed on the floating gate dielectric layer, and the erasing gate structure includes an erasing gate dielectric layer and an erasing gate layer disposed on the erasing gate dielectric layer.

According to another aspect of the present disclosure, a method for forming a memory includes: providing a substrate, wherein the substrate includes a first region, a second region and a third region, wherein the second region is disposed on two sides of the first region, and the second region is disposed between the first region and the third region, and the substrate further includes a floating gate structure material layer; forming a mask structure on the floating gate structure material layer, wherein the mask structure has a first opening, and the first opening exposes a top surface of the floating gate structure material layer on the first region and the second region; forming a first side wall on a side of the first opening, wherein the first side wall is disposed on the top surface of the floating gate structure material layer on the second region; removing a part of the floating gate structure material layer at a bottom of the first opening by taking the first side wall and the mask structure as a mask to form an initial floating gate structure and to form a first gate structure on a side surface of the initial floating gate structure, wherein the first gate structure is electrically coupled with the initial floating gate structure; forming a dielectric structure on a surface of the first gate structure and a source line structure on a surface of the dielectric structure, wherein the source line structure is also disposed on a surface of the first region; removing the mask structure and the initial floating gate structure on the third region and the fourth region to form a floating gate structure on the second region after forming the source line structure; and forming a word line gate structure on the third region.

According to some embodiments, the substrate further has an erasing gate structure material layer disposed on the floating gate structure material layer, wherein the first opening exposes a top surface of the erasing gate structure material layer on the first region and the second region, and the first side wall is disposed on the top surface of the erasing gate structure material layer on the second region.

According to some embodiments, the method further includes: removing a part of the erasing gate structure material layer and the part of the floating gate structure material layer at the bottom of the first opening by taking the first side wall and the mask structure as the mask to form an initial erasing gate structure and the initial floating gate structure before forming the dielectric structure on the surface of the first gate structure and the source line structure on the surface of the dielectric structure; and forming an isolation structure on a side surface of the initial erasing gate structure and forming the first gate structure on a surface of the isolation structure, wherein the first gate structure is electrically coupled with the initial floating gate structure.

According to some embodiments, the method further includes: removing the mask structure, the initial erasing gate structure and the initial floating gate structure on the third region and the fourth region to form an erasing gate structure and a floating gate structure on the second region; wherein the erasing gate structure exposes a top surface of the floating gate structure, and the first side wall is disposed on the erasing gate structure; and wherein the isolation structure is disposed on the side surface of the erasing gate structure, and the first gate structure is disposed on the surface of the isolation structure.

According to some embodiments, a part of the isolation structure is also disposed on the erasing gate structure.

According to some embodiments, the isolation structure has an L-shaped section along an arrangement direction of the first region, the second region and the third region.

According to some embodiments, the first gate structure includes a first gate layer disposed on the surface of the isolation structure and a second gate layer disposed on a surface of the first gate layer and on the isolation structure, and the second gate layer is disposed on the floating gate structure.

According to some embodiments, forming the initial erasing gate structure, the initial floating gate structure, the isolation structure and the first gate structure includes: etching the erasing gate structure material layer by taking the first side wall and the mask structure as the mask until the floating gate structure material layer is exposed to form the initial erasing gate structure and to form a second opening at the bottom of the first opening, wherein the second opening exposes the side surface of the initial erasing gate structure; forming an initial isolation structure on a side surface and a bottom surface of the second opening; forming the first gate layer on a side of the initial isolation structure; etching the initial isolation structure by taking the first gate layer as a mask until a surface of the floating gate structure material layer is exposed to form the isolation structure on a side of the initial erasing gate structure and a part of the floating gate structure material layer; forming a second gate material layer on the surface of the first gate layer and the surface of the floating gate structure material layer; back etching the second gate material layer and the floating gate structure material layer until the surface of the first region is exposed to form the second gate layer on the surface of the first gate layer, and to form the initial floating gate structure, wherein the second gate layer is also disposed on the initial floating gate structure.

According to some embodiments, the source line structure includes a first source line layer disposed on the surface of the dielectric structure and a second source line layer disposed on a surface of the first source line layer and the surface of the first region.

According to some embodiments, forming the dielectric structure and the source line structure includes: forming a dielectric structure material layer on the surface of the first gate structure, the side surface of the initial floating gate structure and the surface of the first region, and forming a first source line gate material layer on a surface of the dielectric structure material layer; back etching the first source line gate material layer and the dielectric structure material layer until the surface of the first region is exposed to form the dielectric structure on the surface of the first gate structure and the side surface of the initial floating gate structure, and to form the first source line layer on the surface of the dielectric structure; and forming the second source line layer on the first source line layer and the first region.

According to some embodiments, before forming the second source line layer on the first source line layer and the first region, the method further includes: performing a first ion implantation on exposed first region to form a first doped region in the first region, and the source line structure is electrically coupled with the first doped region.

According to some embodiments, before forming the first side wall on the side of the first opening, the method further includes: performing a second ion implantation on the first region and the second region at the bottom of the first opening to form a second doped region in the first region and the second region, wherein the first doped region is disposed in the second doped region, and a conductive type of the first doped region is opposite to a conductive type of the second doped region.

According to some embodiments, the conductivity type of the second doped region is P-type, and the conductivity type of the first doped region is N-type.

According to some embodiments, the method further includes: forming a first protective layer on the second source line layer.

According to some embodiments, before forming the word line gate structure on the third region, the method further includes: forming a second side wall on a side surface of the first side wall, a side surface of the erasing gate structure and a side surface of the floating gate structure.

According to some embodiments, the word line gate structure includes a word line gate dielectric layer disposed on a side surface of the second side wall and a surface of the third region and a word line gate layer disposed on a surface of the word line gate dielectric layer.

According to some embodiments, the substrate further includes a fourth region, and the third region is disposed between the second region and the fourth region, wherein before forming the second side wall, the method further includes: performing a third ion implantation on the third region and the fourth region to form a third doped region on the third region and the fourth region.

According to some embodiments, the method further includes: forming a first electrical coupling structure on a top surface of the source line structure; forming a second electrical coupling structure on a top surface of the word line gate structure; and forming a third electrical coupling structure on a surface of the fourth region, wherein the third electrical coupling structure is electrically coupled with the third doped region.

According to some embodiments, the substrate includes a memory area and a peripheral area, and the memory area includes the first region, the second region, the third region and the fourth region, wherein the mask structure, the gate structure material layer and the floating gate structure material layer on the peripheral area are removed after the second side wall is formed, wherein while forming the word line gate structure on the third region, the method further includes: forming a control gate structure on the peripheral area; and forming a source-drain doped region in the substrate on two sides of the control gate structure.

According to some embodiments, after forming the word line gate structure, the method further includes: forming a third side wall on a side of the word line gate structure.

According to some embodiments, the floating gate structure material layer includes a floating gate dielectric material layer and a floating gate material layer disposed on the floating gate dielectric material layer, and the floating gate structure includes a floating gate dielectric layer and a floating gate layer disposed on the floating gate dielectric layer.

According to some embodiments, the erasing gate structure material layer includes an erasing gate dielectric material layer and an erasing gate material layer disposed on the erasing gate dielectric material layer, and the erasing gate structure includes an erasing gate dielectric layer and an erasing gate layer disposed on the erasing gate dielectric layer.

The embodiments of the present disclosure have following beneficial effects:

According to some embodiments, the first gate structure is disposed on the side of the floating gate structure and coupled with the floating gate structure. The first gate structure is equivalent to an extension of the floating gate structure. The source line structure is disposed on the first gate structure, which can increase a coupling area between the source line structure and the floating gate structure, thereby improving the programming efficiency; on the other hand, the source line structure and the floating gate structure are coupled with each other in a direction perpendicular to the surface of the substrate, which can reduce a size of the floating gate structure in a direction parallel to the surface of the substrate, thereby reducing the area of the memory.

Further, the memory also includes an erasing gate structure disposed on the floating gate structure, and the isolation structure is disposed on the side surface of the erasing gate structure. The semiconductor structure has a special erasing gate structure and an isolation structure of an erasing gate window, thus the word line gate structure does not need to have an erasing function, and thus does not need to be subject to a high voltage, so that a thickness of an gate dielectric layer of the word line gate structure can be reduced, a channel current under the word line gate structure can be reduced, and a channel width and length at the bottom of the word line gate structure can be reduced, thereby reducing the area of the memory structure.

Further, the source line structure is directly electrically coupled with the first doped region, and then a first electrical coupling structure is directly formed on a top surface of the source line structure, so that the source line structure can be directly connected and has a small resistance.

### BRIEF DESCRIPTION OF THE DRAWINGS

FIG. 1 is a cross-sectional schematic view of a flash memory;

FIGS. 2 to 14 are cross-sectional structural schematic views showing a process for forming a memory according to an embodiment of the present disclosure; and

FIG. 15 is a cross-sectional structural schematic view of a memory according to another embodiment of the present disclosure.

### DETAILED DESCRIPTION

As described in the background, the performance of the flash memory is poor. The following will be described in combination with the attached drawings.

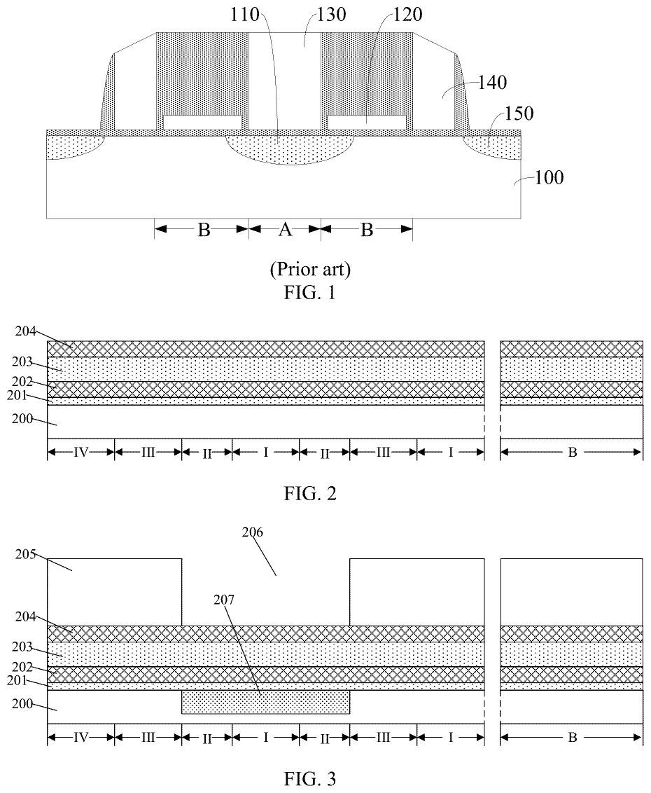

FIG. 1 is a cross-sectional schematic view of a flash memory.

Referring to FIG. 1, a flash memory includes a substrate 100, an erasing gate structure 130, a floating gate structure 120, a word line structure 140, a source region 110 and a bit line structure 150. The substrate 100 includes an erasing area A and a floating gate area B, and the floating gate area B is adjacent to the erasing area A and disposed on both sides of the erasing area A. The erasing gate structure 130 is disposed on the erasing area A, and the floating gate structure 120 is disposed on the floating gate area B. The word line structure 140 is disposed on one side of the floating gate structure 120, and the floating gate structure 120 is disposed between the erasing gate structure 130 and the word line structure 140. The source region 110 is disposed in the erasing area A. The bit line structure 150 is disposed in the substrate 100, and the bit line structure 150 is disposed on one side of the word line structure 140.

In order to increase a coupling voltage between the source region 110 and the floating gate structure 120 during programming, one method is to increase a coupling area between the floating gate structure 120 and the source region 110, thereby improving a coupling rate between the floating gate structure 120 and the source region 110. During programming, due to a high coupling rate, higher coupling voltage is generated on the floating gate structure 120, and more hot electrons are attracted to the floating gate structure 120, thereby realizing the programming of the floating gate structure 120.

However, in the structure of above flash memory, a floating gate channel area accounts for about half of a size of the floating gate structure 120, and the floating gate structure 120 disposed above the source region 110 is used for voltage coupling. In order to improve the voltage of the floating gate structure 120 during programming, it is necessary to ensure that an overlapping area of the source region 110 and the floating gate structure 120 has a large size, which leads to a large size of the entire flash memory and does not conform to the trend of semiconductor device miniaturization.

In order to solve above problems, the present disclosure provides a memory and a method for forming the memory. The first gate structure is disposed on the side of the floating gate structure and coupled with the floating gate structure. The first gate structure is equivalent to an extension of the floating gate structure. The source line structure is disposed on the first gate structure, which can increase a coupling area between the source line structure and the floating gate structure, thereby improving the programming efficiency; on the other hand, the source line structure and the floating gate structure are coupled with each other in a direction perpendicular to the surface of the substrate, which can reduce a size of the floating gate structure in a direction parallel to the surface of the substrate, thereby reducing the area of the memory.

In order to make above purposes, features and beneficial effects of the present disclosure more obvious and understandable, specific embodiments of the present disclosure will be described in detail in combination with the attached drawings.

FIGS. 2 to 14 are cross-sectional structural schematic views showing a process for forming a memory according to an embodiment of the present disclosure.

Referring to FIG. 2, a substrate 200 is provided. The substrate 200 includes a first region I, a second region II and a third region III. The second region II is disposed on both sides of the first region I, and the second region II is disposed between the first region I and the third region III. The substrate 200 has a floating gate structure material layer and an erasing gate structure material layer disposed on the floating gate structure material layer.

In some embodiments, the substrate 200 also includes a fourth region IV, and the third region III is disposed between the second region II and the fourth region IV.

In some embodiments, the substrate 200 includes a memory area and a peripheral area B, and the memory area includes the first region I, the second region II, the third region III and the fourth region IV.

In some embodiments, the floating gate structure material layer includes a floating gate dielectric material layer 201 and a floating gate material layer 202 disposed on the floating gate dielectric material layer 201. The erasing gate structure material layer includes an erasing gate dielectric material layer 203 and an erasing gate material layer 204 disposed on the erasing gate dielectric material layer 203.

The material of the floating gate dielectric material layer 201 and the erasing gate dielectric material layer 203 may include silicon oxide. The material of the floating gate material layer 202 and the erasing gate material layer 204 may include polysilicon.

In some embodiments, the material of the substrate 200 is silicon. In other embodiments, the material of the substrate may also be germanium, silicon germanium, silicon carbide, gallium arsenide or indium gallium. In other embodiments, the substrate may also be a silicon substrate on an insulator or a germanium substrate on an insulator.

Referring to FIG. 3, a mask structure 205 is formed on the erasing gate structure material layer. The mask structure 205 has a first opening 206. The first opening 206 exposes a top surface of the erasing gate structure material layer on the first region I and the second region II.

In some embodiments, the material of the mask structure 205 includes silicon nitride.

Still referring to FIG. 3, a second ion implantation is performed on the first region I and the second region II at a bottom of the first opening 206 to form a second doped region 207 in the first region I and the second region II.

In some embodiments, a conductivity type of the second doped region 207 is P-type.

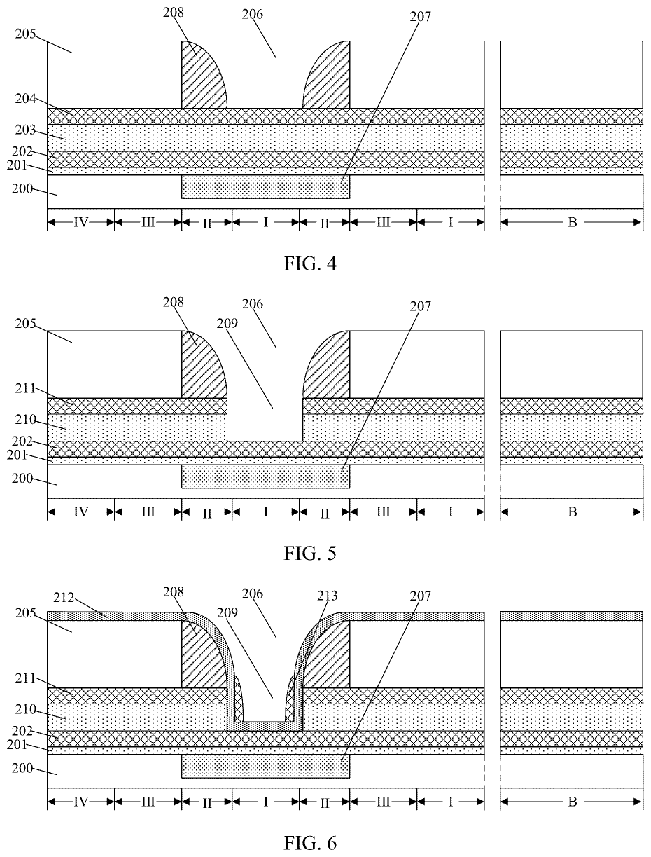

Referring to FIG. 4, a first side wall 208 is formed on a side of the first opening 206, and the first side wall 208 is disposed on the top surface of the erasing gate structure material layer on the second region II.

In some embodiments, the material of the first side wall 208 includes silicon oxide.

The method for forming the first side wall 208 includes: forming a side wall material layer (not shown) on a surface of the mask structure 205, a bottom surface and a side surface of the first opening 206; and back etching the side wall material layer until the top surface of the erasing gate structure material layer is exposed to form the first side wall 208 on the side of the first opening 206.

Next, a part of the erasing gate structure material layer and a part of the floating gate structure material layer at the bottom of the first opening 206 is removed with the first side wall 208 and the mask structure 205 as the mask to form an initial erasing gate structure and an initial floating gate structure, and to form an isolation structure on a side surface of the initial erasing gate structure and a first gate structure on a surface of the isolation structure. The first gate structure is electrically coupled with the initial floating gate structure. The process for forming the initial erasing gate structure, the initial floating gate structure, the isolation structure and the first gate structure are shown in FIGS. 5 to 8.

In some embodiments, a part of the isolation structure is also disposed on the initial erasing gate structure.

In some embodiments, the first gate structure includes a first gate layer disposed on the surface of the isolation structure and a second gate layer disposed on a surface of the first gate layer and the isolation structure, and the second gate layer is disposed on the floating gate structure.

Referring to FIG. 5, the erasing gate structure material layer is etched with the first side wall 208 and the mask structure 205 as the mask until the floating gate structure material layer is exposed to form the initial erasing gate structure, and to form a second opening 209 at the bottom of the first opening 206. The second opening 209 exposes a side surface of the initial erasing gate structure.

In some embodiments, the initial erasing gate structure includes an initial erasing gate dielectric layer 210 and an initial erasing gate layer 211 disposed on the initial erasing gate dielectric layer 210.

Referring to FIG. 6, an initial isolation structure 212 is formed on a side surface and a bottom surface of the second opening 209, and a first gate layer 213 is formed on a side of the initial isolation structure 212.

In some embodiments, the material of the initial isolation structure 212 includes silicon oxide, and the material of the first gate layer 213 includes polysilicon.

The process for forming the initial isolation structure 212 includes a deposition process.

The method for forming the first gate layer 213 includes: forming a gate material layer (not shown) on a surface of the initial isolation structure 212, and back etching the gate material layer until the surface of the initial isolation structure 212 is exposed to form the first gate layer 213 on the side of the initial isolation structure 212.

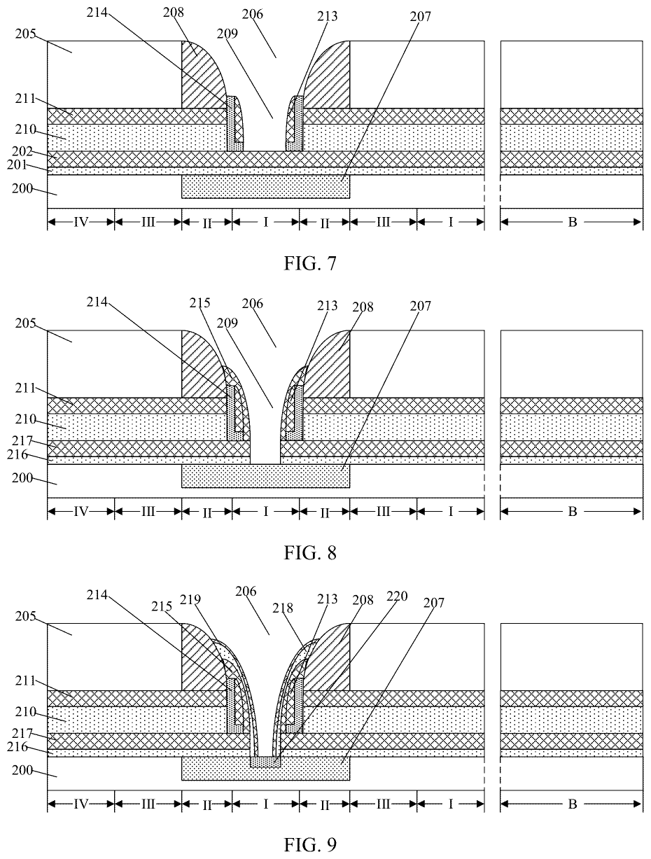

Referring to FIG. 7, the initial isolation structure 212 is etched with the first gate layer 213 as a mask until a surface of the floating gate structure material layer is exposed to form the isolation structure 214 on the side of the initial erasing gate structure and a part of the floating gate structure material layer.

In some embodiment, the isolation structure 214 has an L-shaped section along an arrangement direction of the first region I, the second region II and the third region III.

The isolation structure 214 serves as an erasing window of an erasing gate structure formed subsequently.

Referring to FIG. 8, a second gate material layer (not shown) is formed on a surface of the first gate layer 213 and the surface of the floating gate structure material layer. The second gate material layer and the floating gate structure material layer are back etched until a surface of the first region I is exposed, so that the second gate layer 215 is formed on the surface of the first gate layer 216, and the initial floating gate structure is formed. The second gate layer 215 is also disposed on the initial floating gate structure.

The initial floating gate structure includes an initial floating gate dielectric layer 216 and an initial floating gate layer 217 disposed on the initial floating gate dielectric layer 216.

In some embodiments, the material of the second gate layer 215 includes polysilicon.

The first gate structure includes a first gate layer 213 disposed on a surface of the isolation structure 214 and a second gate layer 215 disposed on a surface of the first gate layer 213 and on the isolation structure 214. The second gate layer 215 is disposed on the initial floating gate structure.

The first gate layer 213 can fill the surface of the L-shaped isolation structure 214, and the second gate layer 215 can increase a surface area of the first gate structure, so as to increase a coupling area of subsequently formed source line structure with the first gate structure.

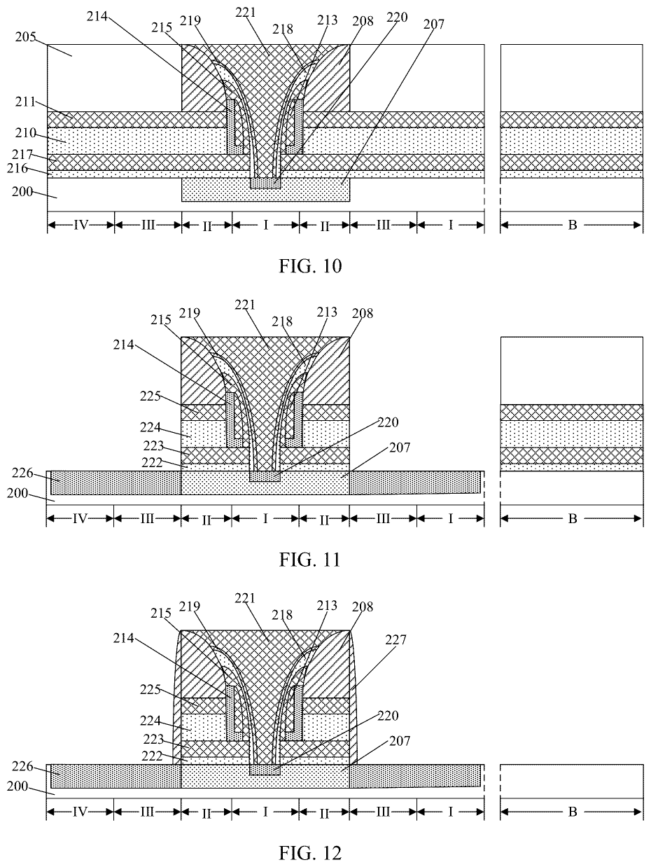

Next, a dielectric structure is formed on a surface of the first gate structure and a source line structure is formed on a surface of the dielectric structure. The source line structure is also disposed on the surface of the first region I. The method for forming the dielectric structure and the source line structure are shown in FIG. 9 and FIG. 10.

Referring to FIG. 9, a dielectric structure 218 is formed on the surface of the first gate structure and the side surface of the initial floating gate structure, and a first source line layer 219 is formed on the surface of the dielectric structure 218.

The method for forming the dielectric structure 218 and the first source line layer 219 includes: forming a dielectric structure material layer (not shown) on the surface of the first gate structure, the side surface of the initial floating gate structure and the surface of the first region I, forming a first source line gate material layer (not shown) on a surface of the dielectric structure material layer, and back etching the first source line gate material layer and the dielectric structure material layer until the surface of the first region I is exposed, so that the dielectric structure 218 is formed on the surface of the first gate structure and the side surface of the initial floating gate structure, and the first source line layer 219 is formed on the surface of the dielectric structure 218.

In some embodiments, the dielectric structure 218 includes a first dielectric layer (not shown), a second dielectric layer (not shown) disposed on a surface of the first dielectric layer, and a third dielectric layer (not shown) on a surface of the second dielectric layer.

The material of the first dielectric layer and the third dielectric layer may include silicon oxide, and the material of the second dielectric layer may include silicon nitride. The dielectric structure 218 is disposed between the first gate structure and the source line structure. The dielectric structure 218 has an ONO structure. The ONO structure has a large dielectric constant, thus a coupling efficiency between the source line structure and the first gate structure can be improved, and thus a coupling efficiency between the source line structure and the floating gate structure can be improved.

In other embodiments, the material of the dielectric structure includes silicon oxide.

In some embodiment, the material of the first source line layer 219 includes polysilicon.

The first source line layer 219 is formed first, making it easier to control the thickness and forming process of a subsequently formed source line structure.

In other embodiments, the first source line layer may be not formed.

Still referring to FIG. 9, after the dielectric structure 218 and the first source line layer 219 are formed, a first ion implantation is performed on the exposed first region I to form a first doped region 220 in the first region I.

The first doped region 220 is disposed in the second doped region 207, and a conductive type of the first doped region 220 is opposite to a conductive type of the second doped region 207.

In some embodiments, the conductive type of the first doped region 220 is N-type.

The first doped region 220 and the second doped region 207 have opposite conductive types, so the first doped region 220 and the second doped region 207 can form a PN junction to realize the function of the memory.

Referring to FIG. 10, a second source line layer 221 is formed on the first source line layer 219 and the first region I to form the source line structure, and the source line structure is electrically coupled with the first doped region 220.

The source line structure includes the first source line layer 219 disposed on the surface of the dielectric structure 218 and the second source line layer 221 disposed on a surface of the first source line layer 219 and the surface of the first region I.

The method for forming the second source line layer 221 includes: forming a source line material layer (not shown) on the first source line layer 219, the mask structure 205 and the first region I, and flattening the source line material layer until the surface of the mask structure 205 is exposed to form the second source line layer 221.

In some embodiments, the material of the second source line layer 221 includes polysilicon.

The source line structure is directly electrically coupled with the first doped region 220, and then a first electrical coupling structure is directly formed on a top surface of the source line structure, so that the source line structure can be directly connected and has a small resistance.

Still referring to FIG. 10, in some embodiments, a first protective layer (not shown) is formed on the second source line layer 221.

The first protective layer can protect the top surface of the second source line layer 221. The material of the first protective layer includes silicon oxide.

In other embodiments, the first protective layer may be not formed.

Still referring to FIG. 11, after the source line structure is formed, the mask structure 205, the initial erasing gate structure and the initial floating gate structure on the third region III and the fourth region IV are removed, so that the erasing gate structure and the floating gate structure are formed on the second region II.

The erasing gate structure includes an erasing gate dielectric layer 224 and an erasing gate layer 225 disposed on the erasing gate dielectric layer 224. The floating gate structure includes a floating gate dielectric layer 222 and a floating gate layer 223 disposed on the floating gate dielectric layer 222.

In some embodiments, the first gate structure is electrically coupled with the floating gate structure.

The first gate structure is disposed on the side of the floating gate structure and coupled with the floating gate structure. The first gate structure is equivalent to an extension of the floating gate structure. The source line structure is disposed on the first gate structure, which can increase a coupling area between the source line structure and the floating gate structure, thereby improving the programming efficiency; on the other hand, the source line structure and the floating gate structure are coupled with each other in a direction perpendicular to the surface of the substrate, which can reduce a size of the floating gate structure in a direction parallel to the surface of the substrate, thereby reducing the area of the memory.

The erasing gate structure is disposed on the floating gate structure, and the isolation structure is disposed on the side surface of the erasing gate structure. The semiconductor structure has a special erasing gate structure and an isolation structure of an erasing gate window, thus the word line gate structure does not need to have an erasing function, and thus does not need to be subject to a high voltage, so that a thickness of an gate dielectric layer of the word line gate structure can be reduced, a channel current under the word line gate structure can be reduced, and a channel width and length at the bottom of the word line gate structure can be reduced, thereby reducing the area of the memory structure.

Still referring to FIG. 11, a third ion implantation is performed on the third region III and the fourth region IV to form a third doped region 226 in the third region III and the fourth region IV.

A conductive type of the third doped region 226 is N-type.

Referring to FIG. 12, a second side wall 227 is formed on a side surface of the first side wall 208, a side surface of the erasing gate structure and a side surface of the floating gate structure.

In some embodiments, the material of the second side wall 227 includes silicon oxide.

The method for forming the second side wall 227 includes: forming a side wall material layer (not shown) on a surface of the third region III, a surface of the fourth region IV, the side surface of the first side wall 208, the side surface of the erasing gate structure, the side surface of the floating gate structure and the second source line layer 221, and back etching the side wall material layer until the surface of the third region III and the surface of the fourth region IV are exposed, so that the second side wall 227 is formed on the side surface of the first side wall 208, the side surface of the erasing gate structure and the side surface of the floating gate structure.

Still referring to FIG. 12, after forming the second side wall 227, the mask structure 205, the erasing gate structure material layer and the floating gate structure material layer on the peripheral area B are removed.

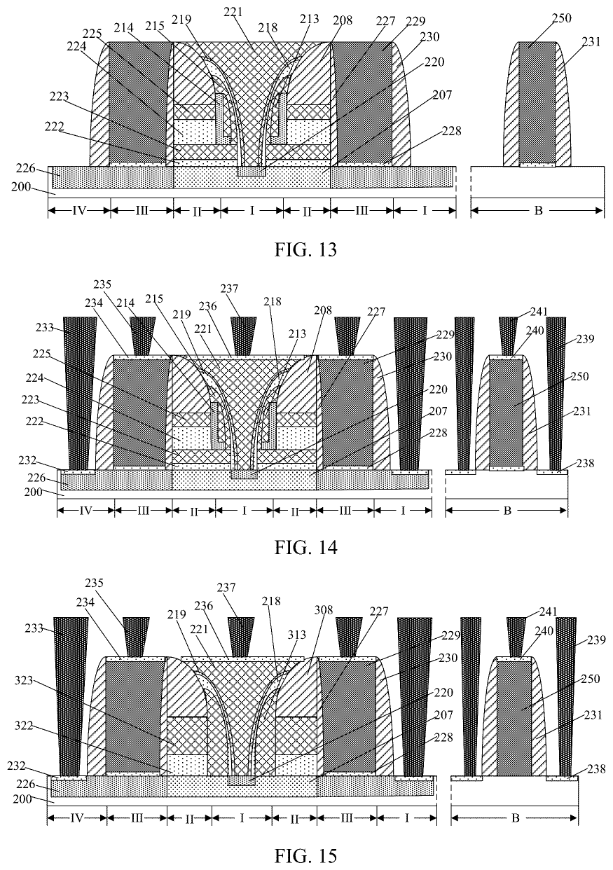

Referring to FIG. 13, a word line gate structure is formed on the third region III.

The word line gate structure includes a word line gate dielectric layer 228 disposed on a side surface of the second side wall 227 and the surface of the third region III, and a word line gate layer 229 disposed on a surface of the word line gate dielectric layer 228.

In some embodiments, the material of the word line gate dielectric layer 228 includes silicon oxide, and the material of the word line gate layer 229 includes polysilicon.

Still referring to FIG. 13, while forming the word line gate structure on the third region III, the method also includes: forming a control gate structure 250 on the peripheral area B. After forming the control gate structure 250, the method also includes: forming a source-drain doped region (not shown) in the substrate 200 on two sides of the control gate structure 250.

The control gate structure 250 includes a control gate dielectric layer (not shown) and a control gate layer (not shown) disposed on the control gate dielectric layer.

Still referring to FIG. 13, a third side wall 230 is formed on a side of the word line structure, and a fourth side wall 231 is formed on a side of the control gate structure 250.

In some embodiments, the materials of the third side wall 230 and the fourth side wall 231 include silicon oxide.

Referring to FIG. 14, a first electrical coupling structure is formed on the top surface of the source line structure, a second electrical coupling structure is formed on a top surface of the word line gate structure, and a third electrical coupling structure is formed on the surface of the fourth region IV. The third electrical coupling structure is electrically coupled with the third doped region 226.

In some embodiments, while forming the first electrical coupling structure, the second electrical coupling structure and the third electrical coupling structure, the method also includes: forming a fourth electrical coupling structure on a top of the control gate structure 230, and forming a fifth electrical coupling structure on the source-drain doped region in the peripheral area B.

The first electrical coupling structure includes a first electrical contact layer 236 and a first conductive layer 237 disposed on the first electrical contact layer 236. The second electrical coupling structure includes a second electrical contact layer 234 and a second conductive layer 235 disposed on the second electrical contact layer 234. The third electrical coupling structure includes a third electrical contact layer 232 and a third conductive layer 233 disposed on the third electrical contact layer 232. The fourth electrical coupling structure includes a fourth electrical contact layer 240 and a fourth conductive layer 241 disposed on the fourth electrical contact layer 240. The fifth electrical coupling structure includes a fifth electrical contact layer 238 and a fifth conductive layer 239 disposed on the fifth electrical contact layer 238.

The materials of the first electrical contact layer 236, the second electrical contact layer 234, the third electrical contact layer 232, the fourth electrical contact layer 240 and the fifth electrical contact layer 238 may include metal silicide, and the metal silicide includes silicon nickel.

The materials of the first conductive layer 237, the second conductive layer 235, the third conductive layer 233, the fourth conductive layer 241 and the fifth conductive layer 239 may include metal or metal nitride. The metal includes one or more combinations of copper, aluminum, tungsten, cobalt, nickel and tantalum. The metal nitride includes one or more combinations of tantalum nitride and titanium nitride.

Accordingly, another embodiment of the present disclosure also provides a memory. Still referring to FIG. 14, the memory includes a substrate 200, a floating gate structure, a first side wall 208, a first gate structure, a dielectric structure, a source line structure and a word line gate structure.

The substrate 200 includes a first region I, a second region II and a third region III. The second region II is disposed on two sides of the first region I, and the second region II is disposed between the first region I and the third region III.

The floating gate structure is disposed on the second region II of the substrate 200.

The first side wall 208 is disposed on the floating gate structure.

The first gate structure is disposed on a side wall of the floating gate structure, and the first gate structure is electrically coupled with the floating gate structure.

The dielectric structure is disposed on a surface of the first gate structure.

The source line structure is disposed on a surface of the dielectric structure, and the source line structure is also disposed on a surface of the first region I.

The word line gate structure is disposed on the third region III.

In some embodiments, the memory also includes an erasing gate structure disposed on the floating gate structure, and the erasing gate structure exposes a top surface of the floating gate structure. The first side wall 208 is disposed on the erasing gate structure.

In some embodiments, the method also includes an isolation structure 214 disposed on a side surface of the erasing gate structure. The first gate structure is disposed on a surface of the isolation structure 214, and the first gate structure is electrically coupled with the floating gate structure.

In some embodiments, a part of the isolation structure 214 is also disposed on the erasing gate structure.

In some embodiments, the isolation structure 214 has an L-shaped section along an arrangement direction of the first region I, the second region II and the third region III.

In some embodiments, the first gate structure includes a first gate layer 213 disposed on the surface of the isolation structure 214 and a second gate layer 215 disposed on a surface of the first gate layer 213 and on the isolation structure, and the second gate layer 215 is disposed on the floating gate structure.

In some embodiments, the source line structure includes a first source line layer 219 disposed on the surface of the dielectric structure and a second source line layer 221 disposed on a surface of the first source line layer 219 and the surface of the first region I.

In some embodiments, the memory also includes a first doped region 220 disposed in the first region I. The source line structure is electrically coupled with the first doped region 220.

In some embodiments, the memory also includes a second doped region 207 disposed in the first region I and the second region II. The first doped region 220 is disposed in the second doped region 207. A conductive type of the first doped region 220 is opposite to a conductive type of the second doped region 207.

In some embodiments, the conductivity type of the second doped region 207 is P-type, and the conductivity type of the first doped region 220 is N-type.

In some embodiments, the memory also includes a second side wall 227 disposed on a side surface of the first side wall 208, a side surface of the erasing gate structure and a side surface of the floating gate structure.

In some embodiments, the word line gate structure includes a word line gate dielectric layer 228 disposed on a side surface of the second side wall 227 and a surface of the third region III and a word line gate layer 229 disposed on a surface of the word line gate dielectric layer 228.

In some embodiments, the substrate 200 also includes a fourth region IV, and the third region III is disposed between the second region II and the fourth region IV. In some embodiments, the substrate 200 also includes a third doped region 226 disposed in the third region III and the fourth region IV.

In some embodiments, the memory also includes: a first electrical coupling structure disposed on a top surface of the source line structure, a second electrical coupling structure disposed on a top surface of the word line structure, and a third electrical coupling structure disposed on a surface of the fourth region IV. The third electrical coupling structure is electrically coupled with the third doped region 226.

In some embodiments, the substrate 200 includes a memory area and a peripheral area B, and the memory area includes the first region I, the second region II, the third region III and the fourth region IV. In some embodiments, the substrate further includes a control gate structure 250 disposed on the peripheral area B, and a source-drain doped region disposed in the substrate 200 on two sides of the control gate structure 250.

In some embodiments, the memory also includes a third side wall 230 disposed on a side of the word line gate structure.

In some embodiments, the erasing gate structure includes an erasing gate dielectric layer 224 and an erasing gate layer 225 disposed on the erasing gate dielectric layer 224, and the floating gate structure includes a floating gate dielectric layer 222 and a floating gate layer 223 disposed on the floating gate dielectric layer 222.

FIG. 15 is a cross-sectional structural schematic view of a memory according to another embodiment of the present disclosure.

Referring to FIG. 15, the memory includes a substrate 200, a floating gate structure, a first side wall 308, a first gate structure 313, a dielectric structure, a source line structure and a word line gate structure.

The substrate 200 includes a first region I, a second region II and a third region III. The second region II is disposed on two sides of the first region I, and the second region II is disposed between the first region I and the third region III.

The floating gate structure is disposed on the second region II of the substrate 200.

The first side wall 308 is disposed on the floating gate structure.

The first gate structure 313 is disposed on a side wall of the floating gate structure, and the first gate structure 313 is electrically coupled with the floating gate structure.

The dielectric structure is disposed on a surface of the first gate structure.

The source line structure is disposed on a surface of the dielectric structure, and the source line structure is also disposed on a surface of the first region I.

The word line gate structure is disposed on the third region III.

In some embodiments, the source line structure includes a first source line layer 219 disposed on the surface of the dielectric structure and a second source line layer 221 disposed on a surface of the first source line layer 219 and the surface of the first region I.

In some embodiments, the memory also includes a first doped region 220 disposed in the first region I. The source line structure is electrically coupled with the first doped region 220.

In some embodiments, the memory also includes a second doped region 207 disposed in the first region I and the second region II. The first doped region 220 is disposed in the second doped region 207. A conductive type of the first doped region 220 is opposite to a conductive type of the second doped region 207.

In some embodiments, the conductivity type of the second doped region 207 is P-type, and the conductivity type of the first doped region 220 is N-type.

In some embodiments, the memory also includes a second side wall 227 disposed on a side surface of the first side wall 208 and a side surface of the floating gate structure.

In some embodiments, the word line gate structure includes a word line gate dielectric layer 228 disposed on a side surface of the second side wall 227 and a surface of the third region III and a word line gate layer 229 located on a surface of the word line gate dielectric layer 228.

In some embodiments, the substrate 200 also includes a fourth region IV, and the third region III is disposed between the second region II and the fourth region IV. In some embodiments, the substrate 200 also includes a third doped region 226 disposed in the third region III and the fourth region IV.

In some embodiments, the memory also includes: a first electrical coupling structure disposed on a top surface of the source line structure, a second electrical coupling structure disposed on a top surface of the word line structure, and a third electrical coupling structure disposed on a surface of the fourth region IV. The third electrical coupling structure is electrically coupled with the third doped region 226.

In some embodiments, the substrate 200 includes a memory area and a peripheral area B, and the memory area includes the first region I, the second region II, the third region III and the fourth region IV. In some embodiments, the substrate further includes: a control gate structure 250 disposed on the peripheral area IV, and a source-drain doped region disposed in the substrate 200 on two sides of the control gate structure 250.

In some embodiments, the memory also includes a third side wall 230 disposed on a side of the word line gate structure.

In some embodiments, the floating gate structure includes a floating gate dielectric layer 322 and a floating gate layer 323 disposed on the floating gate dielectric layer 322.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. A method for forming a memory, comprising:
providing a substrate, wherein the substrate comprises a first region, a second region and a third region, wherein the second region is disposed on two sides of the first region, and the second region is disposed between the first region and the third region, and the substrate further comprises a floating gate structure material layer;
forming a mask structure on the floating gate structure material layer, wherein the mask structure has a first opening, and the first opening exposes a top surface of the floating gate structure material layer on the first region and the second region;
forming a first side wall on a side of the first opening, wherein the first side wall is disposed on the top surface of the floating gate structure material layer on the second region;
removing a part of the floating gate structure material layer at a bottom of the first opening by taking the first side wall and the mask structure as a mask to form an initial floating gate structure and to form a first gate structure on a side surface of the initial floating gate structure, wherein the first gate structure is electrically coupled with the initial floating gate structure;
forming a dielectric structure on a surface of the first gate structure and a source line structure on a surface of the dielectric structure, wherein the source line structure is also disposed on a surface of the first region;
removing the mask structure and the initial floating gate structure on the third region and the fourth region to form a floating gate structure on the second region after forming the source line structure; and
forming a word line gate structure on the third region.

2. The method according to claim 1, wherein the substrate further has an erasing gate structure material layer disposed on the floating gate structure material layer, wherein the first opening exposes a top surface of the erasing gate structure material layer on the first region and the second region, and the first side wall is disposed on the top surface of the erasing gate structure material layer on the second region.

3. The method according to claim 2, further comprising:
removing a part of the erasing gate structure material layer and the part of the floating gate structure material layer at the bottom of the first opening by taking the first side wall and the mask structure as the mask to form an initial erasing gate structure and the initial floating gate structure before forming the dielectric structure on the surface of the first gate structure and the source line structure on the surface of the dielectric structure; and
forming an isolation structure on a side surface of the initial erasing gate structure and forming the first gate structure on a surface of the isolation structure, wherein the first gate structure is electrically coupled with the initial floating gate structure.

4. The method according to claim 3, further comprising:
removing the mask structure, the initial erasing gate structure and the initial floating gate structure on the third region and the fourth region to form an erasing gate structure and a floating gate structure on the second region;
wherein the erasing gate structure exposes a top surface of the floating gate structure, and the first side wall is disposed on the erasing gate structure; and
wherein the isolation structure is disposed on the side surface of the erasing gate structure, and the first gate structure is disposed on the surface of the isolation structure.

5. The method according to claim 4, wherein a part of the isolation structure is also disposed on the erasing gate structure, and the isolation structure has an L-shaped section along an arrangement direction of the first region, the second region and the third region.

6. The method according to claim 5, wherein the first gate structure comprises a first gate layer disposed on the surface of the isolation structure and a second gate layer disposed on a surface of the first gate layer and on the isolation structure, and the second gate layer is disposed on the floating gate structure.

7. The method according to claim 6, wherein forming the initial erasing gate structure, the initial floating gate structure, the isolation structure and the first gate structure comprises:
etching the erasing gate structure material layer by taking the first side wall and the mask structure as the mask until the floating gate structure material layer is exposed to form the initial erasing gate structure and to form a second opening at the bottom of the first opening, wherein the second opening exposes the side surface of the initial erasing gate structure;
forming an initial isolation structure on a side surface and a bottom surface of the second opening;
forming the first gate layer on a side of the initial isolation structure;
etching the initial isolation structure by taking the first gate layer as a mask until a surface of the floating gate structure material layer is exposed to form the isolation structure on a side of the initial erasing gate structure and a part of the floating gate structure material layer;
forming a second gate material layer on the surface of the first gate layer and the surface of the floating gate structure material layer;
back etching the second gate material layer and the floating gate structure material layer until the surface of the first region is exposed to form the second gate layer on the surface of the first gate layer, and to form the initial floating gate structure, wherein the second gate layer is also disposed on the initial floating gate structure.

8. The method according to claim 1, wherein the source line structure comprises a first source line layer disposed on the surface of the dielectric structure and a second source line layer disposed on a surface of the first source line layer and the surface of the first region.

9. The method according to claim 8, wherein forming the dielectric structure and the source line structure comprises:
forming a dielectric structure material layer on the surface of the first gate structure, the side surface of the initial floating gate structure and the surface of the first region, and forming a first source line gate material layer on a surface of the dielectric structure material layer;
back etching the first source line gate material layer and the dielectric structure material layer until the surface of the first region is exposed to form the dielectric structure on the surface of the first gate structure and the side surface of the initial floating gate structure, and to form the first source line layer on the surface of the dielectric structure; and
forming the second source line layer on the first source line layer and the first region.

10. The method according to claim 9, wherein before forming the second source line layer on the first source line layer and the first region, the method further comprises:
performing a first ion implantation on exposed first region to form a first doped region in the first region, and the source line structure is electrically coupled with the first doped region.

11. The method according to claim 10, wherein before forming the first side wall on the side of the first opening, the method further comprises: performing a second ion implantation on the first region and the second region at the bottom of the first opening to form a second doped region in the first region and the second region, wherein the first doped region is disposed in the second doped region, and a conductive type of the first doped region is opposite to a conductive type of the second doped region.

12. The method according to claim 9, further comprising: forming a first protective layer on the second source line layer.

13. The method according to claim 1, wherein before forming the word line gate structure on the third region, the method further comprises: forming a second side wall on a side surface of the first side wall, a side surface of an erasing gate structure and a side surface of the floating gate structure.

14. The method according to claim 13, wherein the word line gate structure comprises a word line gate dielectric layer disposed on a side surface of the second side wall and a surface of the third region and a word line gate layer disposed on a surface of the word line gate dielectric layer.

15. The method according to claim 13, wherein the substrate further comprises a fourth region, and the third region is disposed between the second region and the fourth region, wherein before forming the second side wall, the method further comprises: performing a third ion implantation on the third region and the fourth region to form a third doped region on the third region and the fourth region.

16. The method according to claim 15, further comprising:
forming a first electrical coupling structure on a top surface of the source line structure;
forming a second electrical coupling structure on a top surface of the word line gate structure; and
forming a third electrical coupling structure on a surface of the fourth region, wherein the third electrical coupling structure is electrically coupled with the third doped region.

17. The method according to claim 15, wherein the substrate comprises a memory area and a peripheral area, and the memory area comprises the first region, the second region, the third region and the fourth region, wherein the mask structure, the gate structure material layer and the floating gate structure material layer on the peripheral area are removed after the second side wall is formed, wherein while forming the word line gate structure on the third region, the method further comprises: forming a control gate structure on the peripheral area; and forming a source-drain doped region in the substrate on two sides of the control gate structure.

18. The method according to claim 1, wherein after forming the word line gate structure, the method further comprises: forming a third side wall on a side of the word line gate structure.

19. The method according to claim 1, wherein the floating gate structure material layer comprises a floating gate dielectric material layer and a floating gate material layer disposed on the floating gate dielectric material layer, and the floating gate structure comprises a floating gate dielectric layer and a floating gate layer disposed on the floating gate dielectric layer; wherein the erasing gate structure material layer comprises an erasing gate dielectric material layer and an erasing gate material layer disposed on the erasing gate dielectric material layer, and the erasing gate structure comprises an erasing gate dielectric layer and an erasing gate layer disposed on the erasing gate dielectric layer.

20. A memory formed by the method according to claim 1, comprising:
the substrate comprising the first region, the second region and the third region, wherein the second region is disposed on two sides of the first region, and the second region is disposed between the first region and the third region;
the floating gate structure disposed on the second region of the substrate;
the first side wall disposed on the floating gate structure;
the first gate structure disposed on the side of the floating gate structure, wherein the first gate structure is electrically coupled with the floating gate structure;
the dielectric structure disposed on the surface of the first gate structure;
the source line structure disposed on the surface of the dielectric structure, wherein the source line structure is also disposed on the surface of the first region; and
the word line gate structure disposed on the third region.
